(19) United States
(12) Patent Application Publication
(10) Pub. No.: US 2008/0135990 A1
(43) Pub. Date: Jun. 12, 2008

(54) STRESS-IMPROVED FLIP-CHIP SEMICONDUCTOR DEVICE HAVING HALF-ETCHED LEADFRAME

(75) Inventors: Anthony L. Coyle, Plano, TX (US); Jie-Hua Zhao, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/567,839

(22) Filed: Dec. 7, 2006

(51) Int. Cl. H01L 23/495

(52) U.S. Cl. 257/666; 257/E23.043

(57) ABSTRACT

A semiconductor device (100) with a metal bump (203) on each interior contact pad (202) has a metallic leadframe with lead segments (220) with the first surface (220a) in one plane. The second surface (220b) is castellated across the segment width in two planes so that regions of a first segment thickness (240a) alternate with regions of a reduced (about 50%) second segment thickness (240b); the first thickness regions are in the locations corresponding to the chip interior contact pads (half-etched leadframe). The second segment surface faces the chip so that each first thickness region aligns with the corresponding chip bump. The chip bumps are attached to the corresponding second segment surface using reflow metal. Dependent on the orientation of the attached half-etched segment, thermomechanical stress concentrations away shift from the solder joints into the leadframe metal, or shear stress may reduced.

### FIELD OF THE INVENTION

The present invention is related in general to the field of semiconductor devices and processes and more specifically to high performance flip-chip semiconductor devices, which have half-etched leadframes for improved performance in reliability stress tests.

### DESCRIPTION OF THE RELATED ART

Among the ongoing trends in integrated circuit (IC) technology are the drives towards higher integration, shrinking component feature sizes, and higher speed. Furthermore, the reliability in accelerated stress tests and drop tests is expected to continuously improve. In addition, there is the relentless pressure to keep the cost/performance ratio under control, which translates often into the drive for lower cost solutions. Higher levels of integration include the need for higher numbers of signal lines and power lines, yet smaller feature sizes make it more and more difficult to preserve clean signals without mutual interference.

These trends and requirements do not only dominate the semiconductor chips, which incorporate the ICs, but also the packages, which house and protect the IC chips.

Compared to the traditional wire bonding assembly, the growing popularity of flip-chip assembly in the fabrication process flow of silicon integrated circuit (IC) devices is driven by several facts. First, the electrical performance of the semiconductor devices can commonly be improved when the parasitic inductances correlated with conventional wire bonding interconnection techniques are reduced. Second, flip-chip assembly often provides higher interconnection densities between chip and package than wire bonding. Third, in many designs flip-chip assembly consumes less silicon “real estate” than wire bonding, and thus helps to conserve silicon area and reduce device cost. And fourth, the fabrication cost can often be reduced, when concurrent gang-bonding techniques are employed rather than consecutive individual bonding steps.

The standard method of bump bonding in the fabrication process uses solder balls, or bumps, and their reflow technique. These interconnection approaches are more expensive than wire bonding. In addition, there are severe reliability problems in some stress and life tests of solder ball attached devices. Product managers demand the higher performance of flip-chip assembled products, but they also demand the lower cost and higher reliability of wire bonded devices.

### SUMMARY OF THE INVENTION

Applicants recognize a need to develop a technical approach which considers the complete system consisting of semiconductor chip—device package—external board, in order to provide superior product characteristics, including high reliability, low electrical resistance and inductance, and low cost. The system-wide method of assembling should also provide mechanical stability and high product reliability, especially in accelerated stress tests (temperature cycling, drop test, etc.). The fabrication method should be flexible enough to be applied for different semiconductor product families, including substrates and boards, and a wide spectrum of design and process variations.

One embodiment of the invention is a semiconductor device with a metal bump on each contact pad. For supplying power and ground, a metallic leadframe has elongated lead segments with the first surface in one plane. The second surface is castellated in two planes so that regions of a first segment thickness alternate with regions of a reduced (about 50%) second segment thickness; the first thickness regions are in the locations corresponding to the chip contact pads. The second segment surface faces the chip so that each first thickness region aligns with the corresponding chip bump. The chip bumps are attached to the corresponding second segment surface using reflow metal.

Modeling of thermomechanical stress has shown that using half-etched lead segments and attaching the thick metal portions to the chip bumps causes the stress concentrations to shift away from the solder joints into the leadframe metal, where the stress causes no harm.

Another embodiment of the invention is a flip-chip semiconductor device with a leadframe having half-etched power and ground supply segments. The castellated surface faces away from the chip bumps; consequently, the bumps are solder-attached to the unstructured segment surface. For this embodiment, modeling of thermomechanical has shown the absence of segment bending and thus a lowering of the shear stress, leading to an improvement of the solder joint reliability.

The technical advantages represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a X-ray top view of a Quad FlatPack No-lead (QFN) semiconductor device to highlight the leadframe as an example for embodiments of the invention.

FIG. 2 is a schematic cross section along a power supply lead segment illustrating an embodiment of the invention.

FIG. 3 is a schematic cross section along a ground potential lead segment illustrating an embodiment of the invention.

FIG. 4 is a schematic cross section along a power supply lead segment illustrating another embodiment of the invention.

FIG. 5 is a schematic cross section along a ground potential lead segment illustrating another embodiment of the invention.

### DETAILED DESCRIPTION OF THE PREFERRED EMBODIMENTS

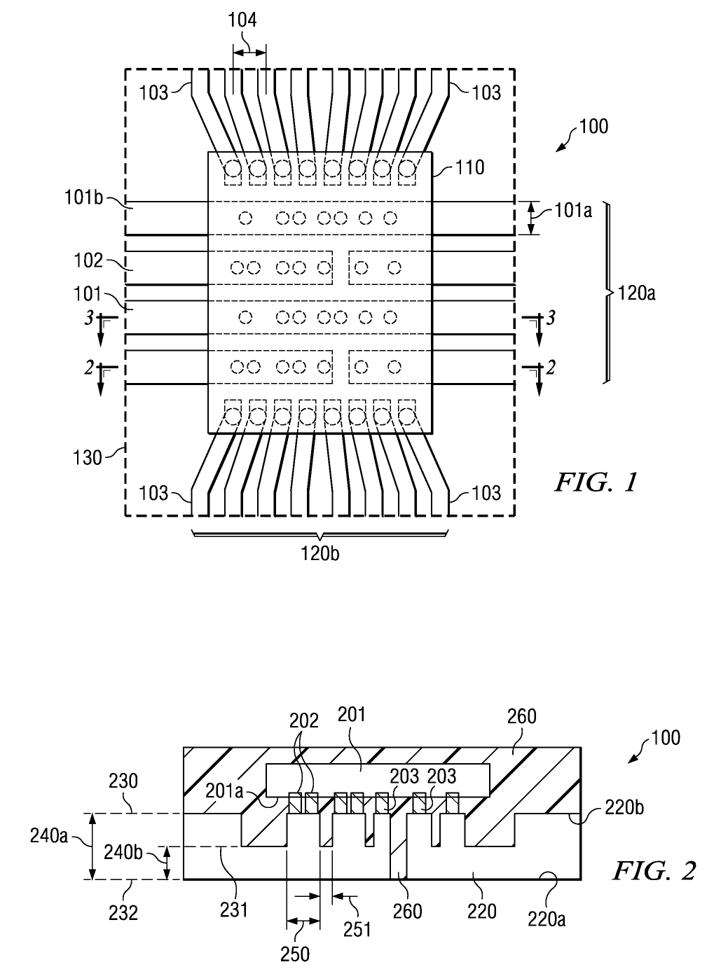

As an example of a device suitable for an embodiment of the invention, FIG. 1 illustrates schematically the top view of a Quad FlatPack No-Lead (QFN) semiconductor device 100 capable of high current operation. The device is shown in X-ray view, wherein the plastic encapsulation compound is transparent; preferably, the encapsulation is a molding compound. The outline of the device package is indicated in FIG. 1 by dashed lines 130; the package of this power device has the dimensions 6.0×6.0 mm.

Embedded in the plastic compound, a chip 110 is assembled on a substrate; in FIG. 1, the chip has the dimensions 3.1×4.0 mm. Preferably, the substrate is a metal leadframe, which includes two sets of segments of various configurations. In principle, the segments of the first set 120a in FIG. 1 with a width 101a of about 200 to 500 μm are intended to handle power supply and ground, the segments of the second set 120b with a width of about 50 to 80 μm will handle signals. As FIG. 1 illustrates, the segments of the second set are oriented about normal to the segments of the first set, when they extend from the respective chip side to the contact pads.

The top view of FIG. 1 looks at the first surface (top) of the leadframe. The second surface is the leadframe bottom surface; it is not shown in FIG. 1, and it is not included in the encapsulation in order to remain exposed for supporting the thermal device performance.

The leadframe is intended to handle an electrical current of more than 30 A; consequently, it is preferably made of copper or a copper alloy in a thickness range between 175 and 250 μm, with a preferred thickness of about 200 μm. The lead segments 101 are intended for ground (drain) and have a width 101a between about 200 and 500 μm; furthermore they are connected to one or more chip contact pads located in the interior of the chip. Alternating with leads 101 are the leads 102, which are intended for power (source); they are preferably also between about 200 and 500 μm wide and are connected to one or more chip contact pads in the chip interior. In contrast, leads 103 have a smaller width (50 to 80 μm) and are preferably connected to a single contact pad, respectively, wherein the pads are located close to the chip perimeter.

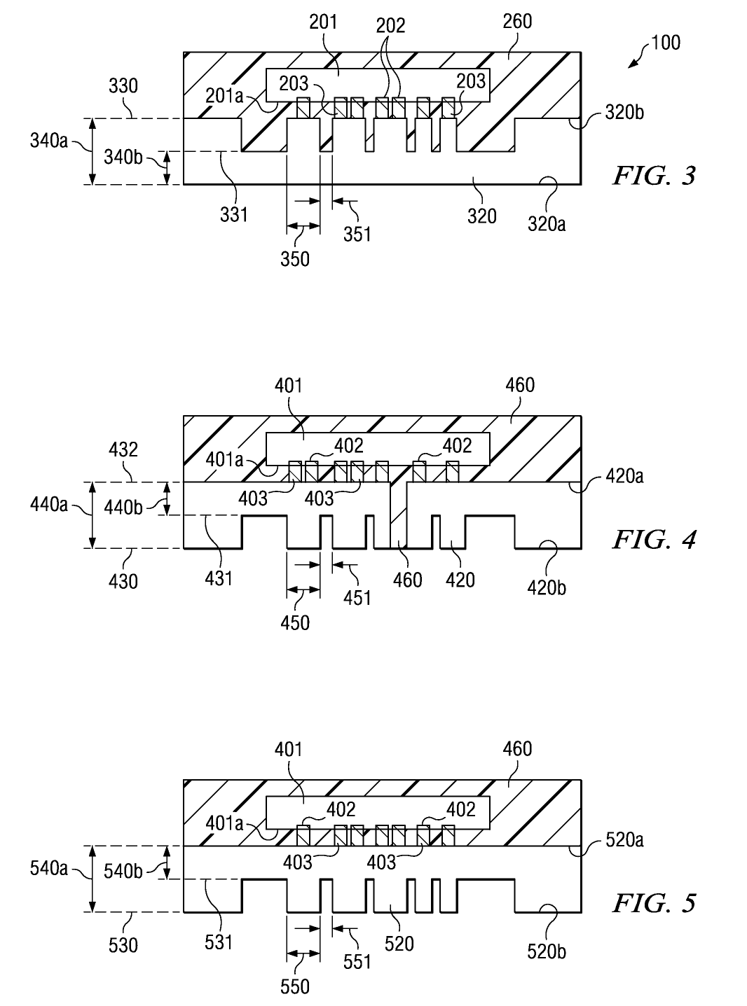

The cross sections FIGS. 2 and 3 depict one embodiment of the invention applied for device 100, FIGS. 4 and 5 depict another embodiment of the invention, also applied for device 100. FIG. 2 illustrates the semiconductor device of FIG. 1 along the cross sectional line A-A, which follows a segment for electrical power supply. FIG. 3 illustrates the semiconductor device of FIG. 1 along the cross sectional line B-B, which follows a segment serving ground potential.

In FIGS. 2 and 3, semiconductor chip 201 has a surface 201a, which includes contact pads 202 at interior pad locations of surface 201a. A bump 203 made of non-reflow metal is attached to each contact pad. Because the device 100 is intended for high current operation, bumps 203 are preferably made of copper, which does not reflow at the temperatures employed at semiconductor device assembly. The bumps have a height between about 30 and 70 μm, and a solderable surface, preferably accomplished by a surface layer of gold or palladium.

In FIG. 2, device 100 further has a substrate with lead segments 220, which serve the electrical power supply (segments 220 belong to the first set of segments; segments of the second set are not shown in FIGS. 2 and 3). The complete segment extends across the chip from one side to the opposite side, and beyond the chip perimeter to the device edge of the encapsulation compound. Preferably, the substrate is a metallic leadframe made of copper or a copper alloy. Alternatively, the substrate may be a tape-like or bulk insulator with elongated copper leads.

The segments 220 have a first surface 220a and a second surface 220b. As FIG. 2 shows, surface 220a is in one plane, designated 232, since the leadframe including the segments had been formed (by etching or stamping) from a metal sheet. In the example of a metallic leadframe, the copper leads have typically a sheet thickness 240a between 150 and 250 μm.

As illustrated in FIG. 2, the second segment surface 220b is castellated in two planes indicated by lines 230 and 231. The rhythm of the castellation forms regions of a first segment thickness, which is the original thickness 240a, and a reduced second segment thickness 240b. Preferably, the second thickness 240b is between about 40 and 60%, more preferably about 50%, of the first segment thickness 240a. For most devices, the second thickness is between about 75 and 125 μm.

The regions of reduced segment thickness extend across the whole segment width. Consequently, the preferred method for fabricating segments of variable thickness is chemical etching; alternatively, mechanical stamping can be used Segments as shown in FIG. 2 are often referred to as half-etched segments. In the preferred fabrication process, the etching or stamping steps are performed while the leadframe is still in strip form.

FIG. 2 indicates that the regions 250 of first thickness and the regions 251 of second thickness alternate so that the regions 250 of first thickness are in locations corresponding to the chip contact pads 202 (interior contact pads). Included in this alternating rhythm is the fact that, where required by the electrical current to be transported, a region 250 of first thickness may have the geometrical size to serve a pair of contact pads rather than just one contact pad.

As illustrated in FIG. 2, the second surface 220b of segment 220 is facing chip 201. With this orientation, segment 220 is aligned with chip 201 so that each region with first thickness 240a is aligned with the corresponding chip bump or bumps 203. After the alignment step, the chip bumps 203 are attached to the corresponding segment surface 220b, preferably by reflow metal (such as solder) or solder paste in the thickness range between about 7 and 15 μm. In the preferred fabrication process, the leadframe is still in strip form, when the alignment of the chips is performed; consequently, the attachment of the chips can be performed as a batch process step

It is preferred for many device types to package the chip after the assembly step. The leadframe strip with the assembled chips is packaged in encapsulation compound 260 so that the first surface 220a of the leadframe remains un-encapsulated and thus available for contact or attachment to external parts. As an example, for a high power QFN (more than 30 A current), the overall device thickness may be 0.9 mm. The preferred packaging process is a transfer molding technique using an epoxy-based molding compound with inorganic fillers. After the compound has been polymerized, the packaged leadframe strip is singulated into the discrete devices 100 illustrated in FIGS. 2 and 3.

As shown in FIG. 3, the leadframe of device 100 further has segments 320, which serve the electrical ground potential. Segments 320 extend across the chip from one side to the opposite side, and beyond the chip perimeter to the device edge of the encapsulation compound. Preferably, segments 320 are substantially parallel to power segments 220 (see also FIG. 1). Like the remainder of the leadframe, segments 320 are preferably made of copper or a copper alloy. As in FIG. 2, the segments have a first surface 320a and a second surface 320b. Surface 320a is in one plane, designated 232, since the elongated segments, with the remainder of the leadframe, had been formed (by etching or stamping) from a metal sheet. For copper as leadframe material, the segments have typically a thickness 340a between 150 and 250 μm.

As illustrated in FIG. 3, the second segment surface 320b is castellated in two planes indicated by lines 330 and 331. The rhythm of the castellation forms regions of a first segment thickness, which is the original thickness 340a, and a reduced second segment thickness 340b. Preferably, the second thickness 340b is between about 40 and 60%, more preferably about 50%, of the first segment thickness 340a. For most devices, the second thickness is between about 75 and 125 μm. The regions of reduced thickness extend across the whole segment width.

FIG. 3 indicates that the regions 350 of first thickness and the regions 351 of second thickness alternate so that the regions 350 of first thickness are in locations corresponding to the chip contact pads 202. Included in this alternating rhythm is the fact that, where required by the electrical current to be transported, a region 350 of first thickness may have the geometrical size to serve a pair of contact pads rather than just one contact pad.

Computer analysis of the stress distribution has been performed, when the system, composed of the silicon chip attached by copper bumps onto the half-etched copper segments and encapsulated in molding compound, is subjected to temperature cycling. Included in the analysis have been shear stress, compressive stress, and tensile stress. The system includes materials of widely different coefficients of thermal expansion (CTE, more than a factor of 10 between silicon and copper). Of particular concern relative to fatigue or cracks are the joints between copper bumps and silicon contact pads.

The stress analysis showed that using half-etched segments and orienting the leadframe for the attachment to the chip contact pads so that the half-etched segments portions face the chip (FIGS. 2 and 3), results in a significant shift of the stress away from the bump joints into the thick portions 250 of the segments. Since the leadframe is made of metal such as copper, the stress can do no harm in the metal. Consequently, in reliability tests using temperature cycling, device 100 shows reduced failure rates caused by bump joint cracking or silicon cratering.

FIGS. 4 and 5 show another embodiment of the invention, wherein the half-etched leadframe segments are assembled onto the semiconductor chips in an orientation so that the leadframe stiffness and thus the shear component of the joint stress are reduced. FIG. 4 is a cross section along line A-A in FIG. 1, FIG. 5 is a cross section along line B-B in FIG. 1.

The semiconductor device of FIGS. 4 and 5 contains a semiconductor chip 401 with a surface 401a including contact pads 402 at interior pad locations. A bump 403 made of non-reflow metal (preferably copper) is attached to each contact pad 402. The device further has a metallic leadframe, preferably made of copper, with lead segments of the first set (segments of the second set are not shown in FIGS. 4 and 5).

In FIG. 4, the segment is designated 420; the segment has a first surface 420a and a second surface 420b. The first segment surface 420a is in one plane 432. The second surface 420b is castellated in two planes 430 and 431 so that regions 450 of a first segment thickness 440a alternate with regions 451 of a reduced second segment thickness 440b. The regions of reduced thickness extend across the whole segment width. The thickness reduction is preferably about 40 to 60% of the original thickness. Furthermore, the regions 450 of the first thickness 440a are in the locations corresponding to the chip contact pads 403.

The castellation of the leadframe segments can be fabricated by stamping or etching the leadframe sheet. Consequently, the leadframe is often referred to as half-etched leadframe.

In the device depicted in FIG. 4, the first segment surface 420a faces the chip contact pads 402. During the alignment process of chip 401 and leadframe segment 420, each first thickness region 450 is aligned with the corresponding chip bump or bumps 402. After the alignment step, the chip bumps 403 are attached to the segment surface 420a (preferably by reflow metals such as solder). For many device types, the device includes a plastic encapsulation material 460 (preferably a molding compound), which packages chip 401 and the attached leadframe segment 420 so that the second surface 420b of the half-etched leadframe segments remains un-encapsulated and thus available for contact or attachment to external parts.

Half-etched segments as depicted in FIG. 4 are preferably used as power supply segments for the device; each segment includes two portions. Half-etched segments preferably used to provide electrical ground potential for the device have the configuration shown in FIG. 5; each segment consists of a single portion 520. The castellation of segment 520 creates two planes indicated by lines 530 and 531. The regions 550 have the first (original) segment thickness 540a, the regions 551 have the second (reduced) thickness 540b, which is preferably between 40 and 60% of the original segment thickness.

The regions 550 of first thickness are in locations corresponding to the chip interior contact pads 402. Using reflow metals (solder), the metal bumps (preferably copper) on the chip contact pads 402 are attached to surface 520a of segment 520 in locations 550 of the first segment thickness 540a For many device types, the device includes a plastic encapsulation material 460 (preferably a molding compound), which packages chip 401 and the attached leadframe segment 520 so that the second surface 520b of the half-etched leadframe segments remains un-encapsulated and thus available for contact or attachment to external parts.

In contrast to the embodiment depicted in FIGS. 2 and 3, the embodiment of FIGS. 4 and 5 has the non-castellated surface of the leadframe segments face the chip; it is encapsulated together with the chip, while the castellated surface is exposed. Computer analysis of the stress distribution has been performed, when the device with this embodiment is subjected to temperature cycling. Of particular concern are stress-induced cracks at the joints between copper bumps and silicon contact pads.

Half-etched segments reduce the leadframe stiffness The segment orientation relative to the chip for attaching the segment to the chip contact pads, as shown in FIGS. 4 and 5, causes only insignificant bending moment in the leadframe. The stress analysis showed that using half-etched segments in the orientation depicted in FIGS. 4 and 5 lowers the shear stress and therefore the overall stress in the silicon joint. Consequently, in reliability tests using temperature cycling, device 100 shows reduced failure rates caused by bump joint cracking or silicon cratering.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

As an example, the invention applies also to flip-chip devices, which employ substrates other than metallic leadframes (for instance polymer-based substrates) with a CTE substantially different from silicon CTE. Half-etching these substrates will lead to lower device failure rates in temperature-cycle reliability tests.

As another example, the invention applies also to devices with chips, which have an extended metallization of the contact pads to provide attachment sites for the copper bumps at some distance from the actual contact pads (often referred to as “bonds over active circuit”).

It is therefore intended that the appended claims encompass any such modifications.

I claim:

1. A semiconductor device comprising:
a semiconductor chip having sides and a surface including contact pads at perimeter and interior locations;
a non-reflow metal bump attached at least to each interior contact pad;
a metallic leadframe having two sets of lead segments;
the segments of the first set having:
a width;
a first and a second surface;
the first surface in one plane;
the second surface castellated across the width to form two segment thicknesses so that regions of the first thickness alternate with regions of the second, reduced thickness, the first thickness regions in the locations corresponding to interior contact pads;
the second segment surface facing the chip so that each first thickness region aligns with the corresponding bumps on interior contact pads, the bumps connecting with the second segment surface by reflow metal; and
a length extending from a chip side to reach one or more interior contact pads;
the segments of the second set having:
a width smaller than the first segment width; and
a length extending from a chip side to reach a perimeter contact pad.

2. A semiconductor device comprising:
a semiconductor chip having sides and a surface including contact pads at perimeter and interior locations;
a non-reflow metal bump attached at least to each interior contact pad;
a metallic leadframe having two sets of lead segments;
the segments of the first set having:
a width;
a first and a second surface;
the first surface in one plane;
the second surface castellated across the width to form two segment thicknesses so that regions of the first thickness alternate with regions of the second, reduced thickness, the first thickness regions in locations corresponding to the interior contact pads;
the first segment surface facing the chip so that each first thickness region aligns with the corresponding bumps on interior contact pads, the bumps connect with the first segment surface by reflow metal; and
a length extending from a chip side to reach one or more interior contact pads;
the segments of the second set having:
a width smaller than the first segment width; and
a length extending from a chip side to reach a perimeter contact pad.

3. The device according to claim 1 and 2 further including plastic encapsulation compound packaging the chip and the attached leadframe segments.

4. The device according to claim 1 and claim 2 wherein the lead segments of the first set provide electrical power and potential for the device.

5. The device according to claim 4 wherein the lead segments of the first set have a width between about 200 and 500 μm.

6. The device according to claim 1 and claim 2 wherein the lead segments of the second set provide electrical signals for the device.

7. The device according to claim 6 wherein the lead segments of the second set have a width of about 50 to 80 μm.

8. The device according to claim 1 and claim 2 wherein the first segment thickness is between about 150 and 250 μm.

9. The device according to claim 1 and claim 2 wherein the second segment thickness is between about 40 and 60% of the first segment thickness.

10. The device according to claim 1 and claim 2 wherein the second thickness is between about 75 and 125 μm.

11. The device according to claim 1 and claim 2 wherein the metal bumps include copper.

12. The device according to claim 1 and claim 2 wherein the leadframe metal includes copper or a copper alloy.

13. The device according to claim 1 and claim 2 wherein the segments of the second set are oriented about normal to the segments of the first set, when they extend from the chip side to the contact pads.
